(19) United States
(12) Patent Application Publication
(10) Pub. No.: US 2021/0013646 A1
(43) Pub. Date: Jan. 14, 2021

(54) METHOD OF FORMING A PROTECTED CONNECTION AND CONNECTOR COMPRISING SAID CONNECTION

(71) Applicant: P2i Ltd, Oxfordshire (GB)

(72) Inventors: Delwyn EVANS, Reading Berkshire (GB); Fred HOPPER, Maidenhead Berkshire (GB); Alex MCLEOD, Bedford Bedfordshire (GB); Graham HUBBARD, Oxfordshire (GB); Neil POULTER, Marlborough Wiltshire (GB)

(21) Appl. No.: 16/980,704

(22) PCT Filed: Mar. 13, 2019
(86) PCT No.: PCT/GB2019/050713

§ 371 Date: Sep. 14, 2020

(30) Foreign Application Priority Data
Mar. 16, 2018 (GB) 1804277.0

(51) Int. Cl. H01R 12/71; B05D 1/00; H01R 13/52; H05K 3/28; H05K 3/32

(52) U.S. Cl. CPC H01R 12/714; B05D 1/62; H01R 13/5216; H05K 2201/0162; H05K 3/284; H05K 3/325; H05K 2203/095; H05K 3/282

(57) ABSTRACT

A method of forming a protected connection between a first connecting element, optionally mounted on a support (202), and a second connecting element, the method comprising: (i) depositing a protective material (210) on the first connecting element and/or on the support; (ii) optionally depositing an overlying coating (212) on the protective material; and (iii) pushing the second connecting element and establishing a connection between the first connecting element and the second connecting element, the connection being protected by the protective material.

### TECHNICAL FIELD

This invention relates to a method of forming a protected connection between a first connecting element and a second connecting element, to a protected connection obtainable by the method, and to a connector.

### BACKGROUND

It is well known that electronic and electrical devices are very sensitive to damage caused by contamination by liquids such as environmental liquids, in particular water. Contact with liquids, either in the course of normal use or as a result of accidental exposure, can lead to short circuiting between electronic components, and irreparable damage to circuit boards, electronic chips etc.

The problem is particularly acute in relation to small portable electronic equipment such as mobile phones, smartphones, pagers, radios, hearing aids, laptops, notebooks, tablet computers, phablets and personal digital assistants (PDAs), which can be exposed to significant liquid contamination when used outside or inside in close proximity of liquids. Such devices are also prone to accidental exposure to liquids, for example if dropped in liquid or splashed.

Other types of electronic or electrical devices may be prone to damage predominantly because of their location, for example outdoor lighting systems, radio antenna and other forms of communication equipment.

It is known in the art that applying a protective coating to electronic substrates presents particular difficulties. An electronic substrate may, in principle, be any electronic or electrical device or component that comprises at least one exposed electrical or electronic contact point. Such substrates are particularly vulnerable, e.g. on account of electrochemical migration, and require highly effective barrier and repellent protection against liquids, frequently over complex surfaces, e.g. circuit board topographies.

It is known to apply conformal coatings to electronic or electrical devices to protect moisture, dust, chemicals and temperature extremes by wet chemistry techniques, such as brushing, spraying and dipping. Conformal coatings take the 3D shape of the substrate on which they are formed and cover the entire surface of the substrate. For example, it is known to apply relatively thick protective coatings to electronic substrates based on parylene technology. A conformal coating formed in this way typically has a thickness of 30-130 μm for an acrylic resin, epoxy resin or urethane resin and 50-210 μm for a silicone resin.

The use of wet chemistry techniques to form these coatings has the disadvantage of the required use of solvents and associated environmental impact. In addition, wet chemistry techniques only allow exposed areas of the device or component to be coated, thus ‘hidden’ areas, for example recesses behind components can be left unprotected. Examples of such hidden areas on a mobile phone include the area under the RF shields, the screen FOG (flex on glass) connector, the inner parts of ZIF (zero insertion force) connectors.

In addition, electrical or electronic contact points of such substrates may lose their functionality if coated with an overly thick protective layer, on account of increased electrical resistance.

As conformal coatings formed by wet chemistry techniques are relatively thick, contact points are typically masked to prevent deposition of coating thereon. However, this leads to complex processing that is impractical on an industrial scale. In addition, the relatively thick coating can cause clogging in areas such as rotating shafts. An alternative method of protecting electronic and electrical devices is P2i's Splash-Proof™ technology, where an ultrathin repellent protective coating is applied to both the outside and the inside of an assembled electronic or electrical device. This restricts liquid ingress whilst additionally preventing any ingressed liquid spreading within the device. Thus, the vast majority of any liquid challenge is prevented from getting into the device in the first instance, whilst there is some additional protection within the device that does not interfere with the functionality of contact points. However, as this technology is directed to a liquid repellent coating rather than a physical barrier, it generally only provides protection against splashing and not against immersion of the device into liquid.

WO2007/083122 discloses electronic and electrical devices having a liquid repellent polymeric coating formed thereon by exposure to pulsed plasma comprising a particular monomer compound, for a sufficient period of time to allow a polymeric layer to form on the surface of the electrical or electronic devices. In general, an item to be treated is placed within a plasma chamber together with material to be deposited in the gaseous state, a glow discharge is ignited within the chamber and a suitable voltage is applied, which may be pulsed.

WO2016/198857 discloses an electronic or electrical device comprising a cross-linked polymeric coating on a surface thereof, wherein the cross-linked polymeric coating is obtainable by exposing the device to a plasma comprising a particular monomer compound and a crosslinking reagent with particular properties for a period of time sufficient to allow formation of the cross-linked polymeric coating on the surface of the device.

There remains a need in the art for highly effective protective coatings without the disadvantages of coatings applied by prior art methods. Such coatings could further enhance the resistance of substrates to liquids, enhance durability, and/or enable more efficient manufacture of protected substrates, particularly in the electronics industry. It is an object of the invention to provide a solution to this problem and/or at least one other problem associated with the prior art.

### SUMMARY OF THE INVENTION

A first aspect of the invention provides a method of forming a protected connection between a first connecting element, optionally mounted on a support, and a second connecting element, the method comprising: (i) depositing a protective material on the first connecting element and/or on the support; (ii) optionally depositing an overlying coating on the protective material; and (iii) pushing the second connecting element and establishing a connection between the first connecting element and the second connecting element, the connection being protected by the protective material.

Advantageously, the protective material is deposited in such a way that the action used in establishing the connection can also establish the protection of the connection by the protective material.

Step (iii) can comprise pushing the second connecting element into the protective material. This can be done sequentially or simultaneously to establishing the connection. When sequential, the second connecting element can be pushed into the protective material and then the connection is established, or the connection can be established and then the second connecting element is pushed into the protective material.

Step (iii) involves pushing the second connecting element and establishing a connection between the first connecting element and the second connecting element. This step generally involves pushing the second connecting element to establish a connection between the first connecting element and the second connecting element.

The method can comprise depositing an overlying coating on the protective material. In this case, step (iii) can comprise pushing the second connecting element through the overlying coating.

In a preferred embodiment, in step (i) the protective material is deposited on the first connecting element.

In an embodiment, in step (iii) the second connecting element is pushed into the protective material, and optionally through the overlying coating, to establish a connection between the first connecting element and the second connecting element.

A preferred embodiment provides a method of forming a protected connection between a first connecting element and a second connecting element, the method comprising:
(i) depositing a protective material on the first connecting element;
(ii) optionally depositing an overlying coating on the protective material; and
(iii) pushing the second connecting element into the protective material, and optionally through the overlying coating, to establish a connection between the first connecting element and the second connecting element, the connection being protected by the protective material.

The protective material can provide protection from liquid, dust or mechanical damage, while it may also act as a fixative for securing the connection.

The protective material may encase the connection. This can mean that the protective material covers an entire surface, or substantially an entire surface, of the connection. In an embodiment, the protective material may seal around the connection. In an embodiment, the protective material covers enough of the surface of the connection to protect it from liquid, dust and/or mechanical damage.

In one embodiment, the second connecting element is pushed into the protective material. This can mean that the second connecting element punctures the surface of the protective material and penetrates the protective material. Alternatively, this can mean that the second connecting element compresses the protective material such that the second connecting element occupies a region of space that would otherwise be occupied by the protective material, for example by pushing a dent, recess or channel into the protective material. In this sense, the second connecting element has been pushed into a region of space that would otherwise be occupied by the protective material. In this embodiment, the protective material will be resiliently biased against the second connecting element. This resilient bias can play a role in protection of the connection.

The connection is protected by the protective material. In a particularly preferred embodiment, the protective material forms a watertight seal around the connection when the connection is established. Advantageously, this prevents the ingress of water that could damage the connection.

In an embodiment, the protective material may be a self-healing material. “Self-healing” refers to the ability of a material to regenerate or repair itself in the event that damage is sustained, for example because new bonds are spontaneously formed when old bonds are broken within the material. Typically, when a self-healing material is damaged, e.g. by pushing the second connecting element through the material, this actuates an automatic healing process which includes a chemical repair process. The chemical repair process can, for example, be based on polymerization, entanglement, or crosslinking, wherein the crosslinking can optionally be reversible.

In an embodiment, the protective material may be a gel. As is well-known in the art, a gel is a nonfluid colloidal network or polymer network that is expanded throughout its whole volume by a fluid.

In an embodiment, the gel comprises a self-healing gel.

In an embodiment, the protective material has a hardness value of 40 or lower according to Shore A hardness, as determined by ASTM D2240. Optionally, the protective material has a hardness value of 35 or lower, 30 or lower, 25 or lower, 20 or lower, 15 or lower, or 10 or lower according to Shore A hardness.

In an embodiment, the protective material has a hardness value of less than 100 according to Shore OO hardness, as determined by ASTM D2240. Optionally, the protective material has a hardness value of 90 or lower, 80 or lower, 70 or lower, 60 or lower, 50 or lower, 40 or lower, 30 or lower, 20 or lower, or 10 or lower according to Shore OO hardness. In an embodiment, the protective material has a hardness value of less than 10 according to Shore OO hardness.

In an embodiment, the protective material has a hardness value of 1 mm/10 or more according to the penetration hardness scale as determined by ISO 2137, 9.38 g hollow cone. (For this measurement method, a larger number indicates a softer material.) Optionally, the protective material has a hardness of 30 mm/10 or more, 40 mm/10 or more, 50 mm/10 or more, 60 mm/10 or more, 70 mm/10 or more, 80 mm/10 or more, 90 mm/10 or more, 100 mm/10 or more, 110 mm/10 or more, 120 mm/10 or more, 130 mm/10 or more, 140 mm/10 or more, 150 mm/10 or more, or 160 mm/10 or more, according to the penetration hardness scale as determined by ISO 2137, 9.38 g hollow cone.

In an embodiment, the protective material has a dielectric strength of more than 5 kV/mm, preferable more than 10 kV/mm.

In an embodiment, depositing the protective material comprises curing, optionally UV curing and/or thermal curing. Thermal curing may take place at room temperature or at temperatures elevated above room temperature. For instance, thermal curing can take place at a temperature of greater than 30° C., 40° C., 50° C., 60° C., 70° C., 80° C. or 90° C. In particular, thermal curing can take place at a temperature between 30 and 100° C., 40 and 90° C., 50 and 80° C., or 60 and 70° C. In a preferred embodiment, the thermal curing takes place at room temperature, for instance 10 to 30° C., 15 to 25° C. or 18 to 22° C., such as at about 17° C., 18° C., 19° C., 20° C., 21° C., 22° C., 23° C. or 24° C.

In an embodiment, depositing the protective material comprises use of a base material and a catalyst. In an embodiment, the base material comprises silicone rubber and/or silicone prepolymers which can be vulcanizable, such as vinyl-containing polysiloxanes and/or hydrosiloxane-containing polysiloxanes. In an embodiment, the catalyst comprises a hydrosilylation initiator or catalyst. In an embodiment, the catalyst comprises platinum. The mix ratio between the base material and the catalyst can be readily determined by a person skilled in the art. For example, the mix ratio between the base material and the catalyst can be from 20:1 to 1:1 by volume. In an embodiment, the mix ratio is from 1:15 to 1:5, or around 10:1 by volume.

The viscosity of the base material before curing can be from 50 cPs to 400,000 cPs, for example from 1000 cPs to 200,000 cPs, or from 10,000 cPs to 100,000 cPs, or about 55,000 cPs, at 23° C.

In an embodiment, the viscosity of the base material before curing is from 50 cPs, 100 cPs, 200 cPs, 500 cPs, 1000 cPs, 10,000 cPs, 20,000 cPs, 30,000 cPs, 40,000 cPs, or 50,000 cPs, and/or the viscosity of the base material before curing is up to 400,000 cPs, 300,000 cPs, 200,000 cPs, 100,000 cPs, 90,000 cPs, 80,000 cPs, 70,000 cPs, 60,000 cPs, or 50,000 cPs.

The viscosity of the catalyst before curing can be from 50 cPs to 400,000 cPs, for example from 500 cPs to 200,000 cPs, or from 750 cPs to 100,000 cPs, or about 1,000 cPs, at 23° C.

In an embodiment, the viscosity of the catalyst before curing is from 50 cPs, 100 cPs, 200 cPs, 500 cPs, 750 cPs, or 1000 cPs, and/or the viscosity of the catalyst before curing is up to 400,000 cPs, 300,000 cPs, 200,000 cPs, 100,000 cPs, 90,000 cPs, 80,000 cPs, 70,000 cPs, 60,000 cPs, 50,000 cPs, 40,000 cPs, 30,000 cPs, 20,000 cPs, 10,000 cPs, 5000 cPs, 4000 cPs, 3000 cPs, 2000 cPs or 1000 cPs.

The viscosity of the mixture of the base material and the catalyst before curing can be from 50 cPs to 400,000 cPs, for example from 50 cPs to 400,000 cPs, or from 50 cPs to 400,000 cPs, or about 42,000 cPs, at 23° C.

In an embodiment, the viscosity of the mixture of the base material and the catalyst before curing is from 50 cPs, 100 cPs, 200 cPs, 500 cPs, 1000 cPs, 10,000 cPs, 20,000 cPs, 30,000 cPs, 40,000 cPs, or 50,000 cPs, and/or the viscosity of the mixture of the base material and the catalyst before curing is up to 400,000 cPs, 300,000 cPs, 200,000 cPs, 100,000 cPs, 90,000 cPs, 80,000 cPs, 70,000 cPs, 60,000 cPs, 50,000 cPs, or 45,000 cPs.

In an embodiment, the protective material is deposited as a plurality of discrete units.

In an embodiment, the protective material is deposited directly onto the first connecting element.

In the method according to the first aspect of the invention, a connection is established between the first connecting element and the second connecting element. The connection is thus an interface between the first connecting element and the second connecting element. The first connecting element and the second connecting element may constitute a connector. Thus, the connection may be a connector interface.

The connection can be an electrical connection. The first connecting element and the second connecting element can constitute an electrical connector. With an electrical connection, the protective material protects electrically conductive surfaces of the connection (i.e. electrically conductive surfaces of the first connecting element and the second connecting element). In other words, the electrically conductive surfaces are protected from exposure to water or other contaminants. For example, where a connecting element is an insulated wire with a section of insulation removed to expose the electrically conductive core, the protective material protects the connection and any remaining exposed electrically conductive core. In certain embodiments where the insulation is removed only on one side of a wire, the exposed core can be protected by pushing the exposed core against (i.e. into but without puncturing or penetrating) a deposit of protective material.

In an embodiment, the electrical connector is selected from electrical connectors that include spring-type contacts, electrical connectors with contacts that comprise spring-loaded pins, plug-in type electrical connectors, contact pads, board-to-board (B2B) connectors, and zero insertion force (ZIF) connectors. Preferably, the electrical connector is selected from a spring connector, a contact pad, a board-to-board (B2B) connector and a zero insertion force (ZIF) connector.

In embodiments of the invention, the electrical connector and/or the first connecting element forms part of, or is present on, an electronic component such as e.g. a printed circuit board (PCB), a printed circuit board array (PCBA), a transistor, resistor, or semi-conductor chip. The electronic component may be an internal component of an electronic device, e.g. a mobile phone.

In an embodiment, the method according to the first aspect of the invention comprises step (ii) of depositing an overlying coating on the protective material. The overlying coating can, for example, be deposited by plasma deposition, by chemical vapour deposition (CVD), or by wet chemistry techniques such as brushing, spraying and dipping. The overlying coating can, for example, be a plasma deposited coating, a CVD coating, or a spray-on coating. In an embodiment, the overlying coating can be a Parylene coating.

In an embodiment, depositing the overlying coating in step (ii) comprises forming a plasma deposited layer.

In an embodiment, depositing the overlying coating in step (ii) comprises exposing the protective material to a plasma comprising a monomer compound for a period of time sufficient to allow the overlying coating to form.

Surprisingly, using a protective material underneath a plasma deposited layer allows the second connecting element to be pushed through the protective material and the plasma deposited layer while maintaining the desired properties of the coating such as its waterproof properties. No demasking step is required and the connecting elements are protected from corrosion. Furthermore, the second connecting element does not need to be separately processed in order to establish a protected connection.

In an embodiment, the monomer compound is a compound of formula (I):

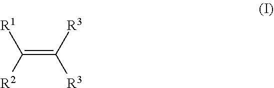

wherein

each of R¹, R² and R⁴ is independently selected from hydrogen, halogen, optionally substituted branched or straight chain C₁-C₆ alkyl, optionally substituted C₃-C₈ cycloalkyl, optionally substituted C₃-C₁₂ aryl, and

R³ is selected from:

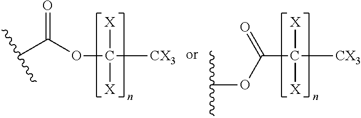

wherein each X is independently selected from hydrogen, halogen, optionally substituted branched or straight chain C₁-C₆ alkyl, optionally substituted C₃-C₅ cycloalkyl, and optionally substituted C₃-C₁₂ aryl, and

n is an integer from 1 to 27.

Throughout this specification, unless expressly stated otherwise:
An “optionally substituted” group may be unsubstituted, or substituted with one or more, for example one or two, substituents. These substituents may, for example, be selected from alkyl, cycloalkyl, alkenyl, alkynyl, aryl, heteroaryl and heterocyclyl groups; carboxylic acids and carboxylate ions; carboxylate esters; carbamates; alkoxyl groups; ketone and aldehyde groups; amine and amide groups; —OH; —CN; —NO₂; and halogens.
An alkyl group may be a straight or branched chain alkyl group. The alkyl group may be C₁ to C₆ alkyl, or C₁ to C₅ alkyl, or C₁ to C₄ alkyl, or C₁ to C₃ alkyl, or C₁ to C₂ alkyl. The alkyl group may, for example, be selected from methyl, ethyl, n-propyl, isopropyl, n-butyl, isobutyl, tert-butyl, sec-butyl, n-pentyl, neopentyl, n-hexyl, isohexyl, and 3-methyl pentyl.
The cycloalkyl group may be C₃ to C₈ cycloalkyl, C₃ to C₇ cycloalkyl, C₃ to C₆ cycloalkyl, C₄ to C₆ cycloalkyl, or C₅ to C₆ cycloalkyl.
An aryl group may be a monocyclic or bicyclic aromatic group. The aryl group may contain from 3 to 12 carbon atoms. The aryl group may be C₃ to C₁₂ aryl, C₅ to C₁₂ aryl, C₅ to C₁₀ aryl, C₅ to C₈ aryl, or C₅ to C₆ aryl.
A halogen group may be fluorine (F), chlorine (Cl), bromine (Br), or iodine (I), preferably fluorine (F).

In an embodiment, each of R¹, R² and R⁴ is independently selected from hydrogen, methyl, ethyl, n-propyl, isopropyl, n-butyl, isobutyl, tert-butyl, sec-butyl, n-pentyl, neopentyl, n-hexyl, isohexyl, and 3-methylpentyl. In an embodiment, each of R¹, R² and R⁴ is independently selected from hydrogen and methyl. In an embodiment, R¹ and R² are both hydrogen. In an embodiment, R⁴ is methyl. In an embodiment, each of R¹, R² and R⁴ is hydrogen.

In an embodiment, each X is independently selected from hydrogen, halogen, methyl, ethyl, n-propyl, isopropyl, n-butyl, isobutyl, tert-butyl, sec-butyl, n-pentyl, neopentyl, n-hexyl, isohexyl, and 3-methylpentyl. In an embodiment, each of X is independently selected from hydrogen and halogen. In an embodiment, each X is hydrogen. In an embodiment, each X is halogen. In an embodiment, each X is F.

n is an integer from 1 to 27. In an embodiment, the lower value of the possible range for n is 1, 2, 3, 4, 5, 6, 7, 8, 9, 10, 11, 12, 13, 14, 15, 16, 17, 18, 19, 20, 21, 22, 23, 24, 25 or 26 and/or the upper value of the possible range for n is 27, 26, 25, 24, 23, 22, 21, 20, 19, 18, 17, 16, 15, 14, 13, 12, 11, 10, 9, 8, 7, 6, 5, 4, 3 or 2.

In an embodiment, the monomer compound is a compound of formula (Ia):

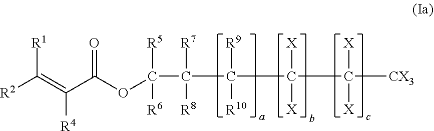

wherein

each of R¹, R², R⁴, and R⁵ to R¹⁰ is independently selected from hydrogen and optionally substituted C₁-C₆ branched or straight chain alkyl;

each X is independently selected from hydrogen and halogen;

a is from 0 to 10; b is from 2 to 14; and c is 0 or 1.

In an embodiment, the monomer compound is a compound of formula (Ib):

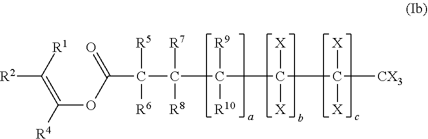

wherein

each of R¹, R², R⁴, and R⁵ to R¹⁰ is independently selected from hydrogen and optionally substituted C₁-C₆ branched or straight chain alkyl;

each X is independently selected from hydrogen and halogen;

a is from 0 to 10; b is from 2 to 14; and c is 0 or 1.

In an embodiment, each of R¹, R², R⁴ and R⁵ to R¹⁰ is independently selected from hydrogen, methyl, ethyl, n-propyl, isopropyl, n-butyl, isobutyl, tert-butyl, sec-butyl, n-pentyl, neopentyl, n-hexyl, isohexyl, and 3-methylpentyl.

In an embodiment, each of R¹, R² and R⁴ is independently selected from hydrogen and methyl. In an embodiment, R¹ and R² are both hydrogen. In an embodiment, R⁴ is methyl. In an embodiment, each of R¹, R² and R⁴ is hydrogen.

In an embodiment, each of R⁵ to R¹⁰ is independently selected from hydrogen and methyl.

In an embodiment, R⁵ and R⁶ are hydrogen. In an embodiment, R⁵, R⁶, R⁷ and R⁸ are hydrogen. In an embodiment, each of R⁵ to R¹⁰ is hydrogen.

In an embodiment, each X is independently selected from hydrogen, halogen, methyl, ethyl, n-propyl, isopropyl, n-butyl, isobutyl, tert-butyl, sec-butyl, n-pentyl, neopentyl, n-hexyl, isohexyl, and 3-methylpentyl. In an embodiment, each of X is independently selected from hydrogen and halogen. In an embodiment, each X is hydrogen. In an embodiment, each X is halogen. In an embodiment, each X is F.

a is an integer from 0 to 10. In an embodiment, the lower value of the possible range for a is 0, 1, 2, 3, 4, 5, 6, 7, 8 or 9 and/or the upper value of the possible range for a is 10, 9, 8, 7, 6, 5, 4, 3, 2 or 1.

b is an integer from 2 to 14. In an embodiment, the lower value of the possible range for b is 2, 3, 4, 5, 6, 7, 8, 9, 10, 11, 12 or 13 and/or the upper value of the possible range for b is 14, 13, 12, 11, 10, 9, 8, 7, 6, 5, 4, or 3.

In an embodiment, c is 0. In an embodiment, c is 1.

In an embodiment, a and c are each 0.

In an embodiment, a and c are each independently 0 or 1; and b is from 3 to 7.

In an embodiment, p=a+b+c+1; a and c are each independently 0 or 1; b is from 3 to 7, and p is from 4 to 10.

In an embodiment, the monomer compound is a compound of formula (Ic):

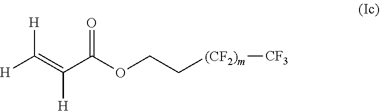

wherein m is from 1 to 10.

m is an integer from 0 to 10. In an embodiment, the lower value of the possible range for m is 0, 1, 2, 3, 4, 5, 6, 7, 8 or 9 and/or the upper value of the possible range for m is 10, 9, 8, 7, 6, 5, 4, 3, 2 or 1.

In an embodiment, the compound of formula (Ic) is selected from 1H,1H,2H,2H-perfluorohexyl acrylate (PFAC4), 1H,1H,2H,2H-perfluorooctyl acrylate (PFAC6), 1H,1H,2H,2H-perfluorodecyl acrylate (PFAC8) and 1H,1H,2H,2H-perfluorododecyl acrylate (PFAC10).

In an embodiment, the monomer compound used to form the coating layer X is a compound of formula (Id):

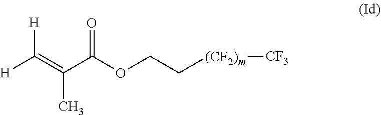

wherein m is from 1 to 10.

m is an integer from 0 to 10. In an embodiment, the lower value of the possible range for m is 0, 1, 2, 3, 4, 5, 6, 7, 8 or 9 and/or the upper value of the possible range for m is 10, 9, 8, 7, 6, 5, 4, 3, 2 or 1.

In an embodiment, the compound of formula (Id) is selected from 1H,1H,2H,2H-perfluorohexyl methacrylate (PFMAC4), 1H,1H,2H,2H-perfluorooctyl methacrylate (PFMAC6) and 1H,1H,2H,2H-perfluorodecyl methacrylate (PFMAC8).

In an embodiment, the monomer compound is a compound of formula (Ie):

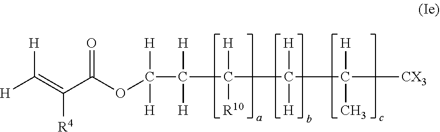

wherein R⁴, R¹⁰ of a, b and c are as described above.

In an embodiment, q=a+b+c+1; a and c are each independently 0 or 1; b is from 3 to 7, and q is from 4 to 10.

In an embodiment, the monomer compound is a compound of formula (If):

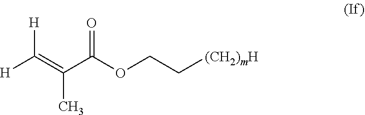

wherein m is from 2 to 12.

In an embodiment, the monomer compound may be selected from ethyl hexyl acrylate, hexyl acrylate, decyl acrylate, lauryl dodecyl acrylate and iso decyl acrylate.

In an embodiment, the monomer compound is a compound of formula (Ig):

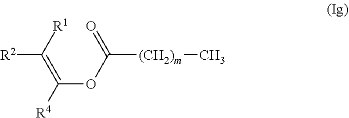

wherein R¹, R² and R⁴ are as described above, and m is from 4 to 14.

In an embodiment, the monomer compound is a compound of formula (Ih):

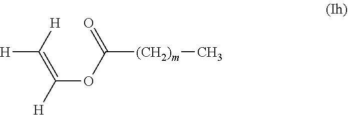

wherein m is from 4 to 14.

In an embodiment, in step (ii), the protective material is exposed to a plasma comprising the monomer compound and a crosslinking reagent.

In an embodiment, the crosslinking reagent comprises two or more unsaturated bonds attached by means of one or more linker moieties.

In an embodiment, the crosslinking reagent has a boiling point of less than 500° C. at standard pressure.

In an embodiment, the crosslinking reagent is independently selected from a compound of formula (II) or (III):

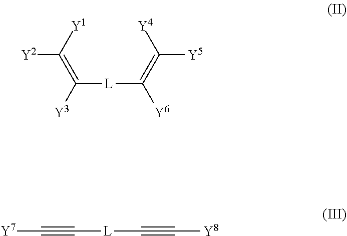

wherein

Y¹, Y², Y³, Y⁴, Y⁵, Y⁶, Y⁷ and Y⁸ are each independently selected from hydrogen, optionally substituted branched or straight chain C₁-C₆ alkyl, optionally substituted C₁-C₆ cycloalkyl, and optionally substituted C₁-C₆ aryl; and

L is a linker moiety.

In an embodiment, group L has the formula:

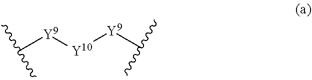

wherein

each Y⁹ is independently selected from a bond, —O—, —O—C(O)—, —C(O)—O—, —Y¹¹—O—C(O)—, —C(O)—O—Y¹¹—, —OY¹¹—, and —Y¹¹O—, wherein Y¹¹ is an optionally substituted branched, straight chain or cyclic C₁-C₈ alkylene; and

Y¹⁰ is selected from an optionally substituted branched, straight chain or cyclic C₁-C₈ alkylene and a siloxane group.

In an embodiment, each Y⁹ is a bond.

In an embodiment, each Y⁹ is —O—.

In an embodiment, each Y⁹ is a vinyl ester or vinyl ether group.

In an embodiment, Y¹⁰ has the formula:

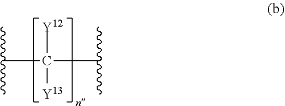

wherein each Y¹² and Y¹³ is independently selected from hydrogen, halogen, optionally substituted cyclic, branched or straight chain C₁-C₈ alkyl, or —OY¹⁴, wherein Y¹⁴ is selected from optionally substituted branched or straight chain C₁-C₈ alkyl or alkenyl, and

n″ is an integer from 1 to 10.

In an embodiment, each Y¹² is hydrogen and each Y¹³ is hydrogen, such that Y¹⁰ is a linear alkylene chain. For this embodiment, Y⁹ can for example be a vinyl ester or vinyl ether group.

In an embodiment, each Y¹² is fluoro and each Y¹³ is fluoro, such that Y¹⁰ is a linear perfluoroalkylene chain.

n″ is an integer from 0 to 10. In an embodiment, the lower value of the possible range for n″ is 0, 1, 2, 3, 4, 5, 6, 7, 8 or 9 and/or the upper value of the possible range for n″ is 10, 9, 8, 7, 6, 5, 4, 3, 2 or 1. In an embodiment, n is from 4 to 6.

In an embodiment, Y¹⁰ has the formula:

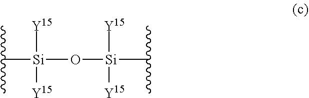

wherein each Y¹⁵ is independently selected from optionally substituted branched or straight chain C₁-C₆ alkyl.

In an embodiment, each Y¹⁵ is methyl. In an embodiment, each Y⁹ is a bond.

In an embodiment, Y¹⁹ has the formula:

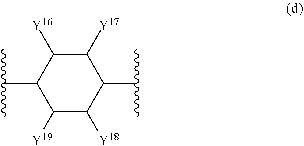

wherein Y¹⁶, Y¹⁷, Y¹⁸ and Y¹⁹ are each independently selected from hydrogen and optionally substituted branched or straight chain C₁-C₈ alkyl or alkenyl. In an embodiment, the alkenyl group is vinyl.

In an embodiment, Y¹⁸ is hydrogen or vinyl, and Y¹⁶, Y¹⁷ and Y¹⁹ are each hydrogen. In an embodiment, each of Y¹⁶, Y¹⁷, Y¹⁸ and Y¹⁹ is hydrogen. In another embodiment Y¹⁸ is vinyl, and Y¹⁶, Y¹⁷ and Y¹⁹ are each hydrogen.

In an embodiment, group L has one of the following structures:

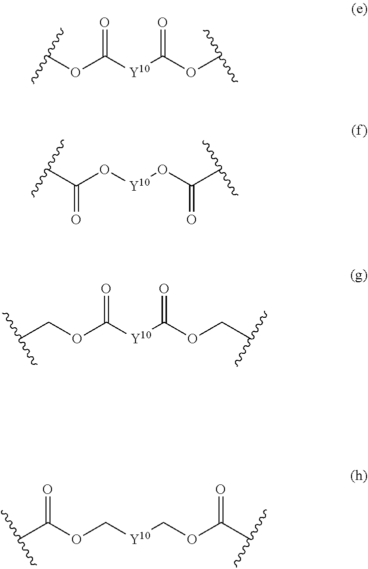

In an embodiment, group L has one of the following structures:

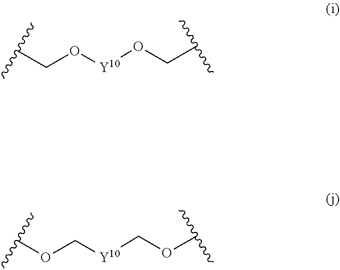

For L according structure (e), Y¹⁰ can for example be an alkylene chain or a cycloalkylene, such as those shown in structures (b) and (d) above. The alkylene chain may for example be a straight chain alkylene chain.

When Y¹⁰ is a cycloalkylene, this can for example be cyclohexylene, such as 1,4-cyclohexylene.

For L according to structure (f), Y¹⁰ can for example be structure (b), e.g. an alkylene or fluoroalkylene chain.

For L according to structure (g), Y¹⁰ can for example be a cycloalkylene, such as the cyclohexylene according to structure (d).

For L according to structure (h), Y¹⁰ can for example be structure (b) wherein each Y¹² and Y¹³ is F, i.e. a perfluoroalkylene chain.

For L according to structure (i) or structure (j), Y¹⁰ can for example be alkylene or cycloalkylene. Optionally the alkylene or cycloalkylene may be substituted with one or more vinyl groups or alkenyl ether groups, for example one or more vinyl ether groups.

When each Y⁹ is a bond, each Y¹⁰ may for example be any of structures (b), (c) and (d).

In an embodiment Y¹⁰ is a straight chain alkylene such that the crosslinking reagent is a diene, such as for example a heptadiene, octadiene, or nonadiene; in an embodiment it is 1,7-octadiene.

When each Y⁹ is O, each Y¹⁰ may for example be a branched or straight chain C₁-C₆ alkylene, preferably a straight chain alkylene, most preferably a C₄ straight chain alkylene. In an embodiment the crosslinking reagent is 1,4-butanediol divinyl ether.

It will be understood that each Y⁹ group can be combined with any other Y⁹ group and Y¹⁰ group to form the crosslinking reagent.

The skilled person will be aware of possible substituents for each of the cyclic, branched or straight chain C₁-C₈ alkylene groups mentioned above. The alkylene groups may be substituted at one or more positions by a suitable chemical group. Halo substituents are preferred, with fluoro substituents most preferred. Each C₁-C₈ alkylene group may for example be a C₁-C₃, C₂-C₆, or C₆-C₈ alkylene group.

In an embodiment, the crosslinking reagent has alkyl chains for Y¹⁰ and vinyl ester or vinyl ether groups on either side.

In an embodiment, the crosslinking reagent is independently selected from divinyl adipate (DVA), 1,4-butanediol divinyl ether (BDVE), 1,4-cyclohexanedimethanol divinyl ether (CDDE), 1,7-octadiene (17OD), 1,2,4-trivinylcyclohexane (TVCH), 1,3-divinyltetramethyldisiloxane (DVTMDS), diallyl 1,4-cyclohexanedicarboxylate (DCHD), 1,6-divinylperfluorohexane (DVPFH), 1H,1H,6H,6H-perfluorohexanediol diacrylate (PFHDA) and glyoxal bis(diallyl acetal) (GBDA).

In an embodiment, the crosslinking reagent is divinyl adipate (DVA).

In an embodiment, the crosslinking reagent is 1,4-butanediol divinyl ether (BDVE).

In an embodiment, for the compound of formula (III), group L can for example be selected from a branched or straight chain C₁-C₈ alkylene or an ether group. L may for example be a C₃, C₄, C₅, or C₆ alkylene, preferably a straight chain alkylene.

Chemical structures of crosslinking reagents are set out below in Table 1.

TABLE 1
Crosslinking reagents

| | |
|---|---|
| Divinyl Adipate (DVA) | 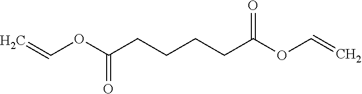 |
| 1,4 Butanediol divinyl ether (BDVE) | 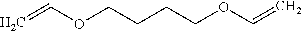 |
| 1,4 Cyclohexanedimethanol divinyl ether (CDDE) | 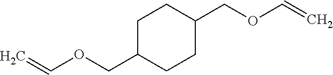 |
| 1,7-Octadiene (17OD) | 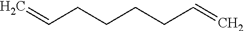 |
| 1,2,4-Trivinylcyclohexane (TVCH) | 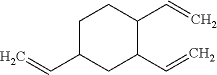 |
| 1,3- Divinyltetramethyldisiloxane (DVTMDS) | 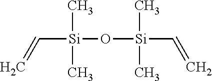 |
| Diallyl 1,4 cyclohexanedicarboxylate (DCHD) | 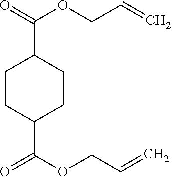 [SMILES: C=CCOC(=O)C1CCC(C(=O)OCC=C)CC1] |
| 1,6-Divinylperfluorohexane (DVPFH) | 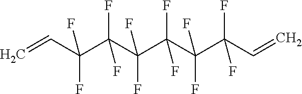 [SMILES: C=CC(F)(F)C(F)(F)C(F)(F)C(F)(F)C(F)(F)C(F)(F)C=C] |
| 1H,1H,6H,6H- Perfluorohexanediol diacrylate (PFHDA) | 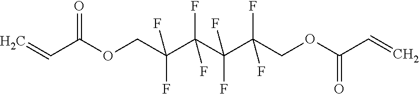 [SMILES: C=CC(=O)OCC(F)(F)C(F)(F)C(F)(F)C(F)(F)COC(=O)C=C] |
| GBDA | 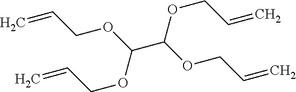 [SMILES: C=CCOC(OCC=C)C(OCC=C)OCC=C] |
| 1,6-heptadiyne | 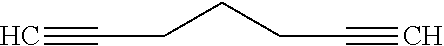 |
| 1,7-heptadiyne | 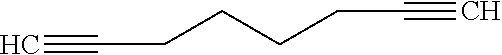 |
| 1,8-heptadiyne | 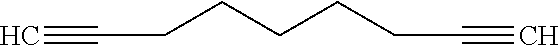 |
| Propargyl ether | 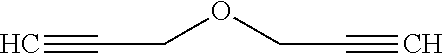 |

In an embodiment, in step (ii) of the method according to the first aspect of the invention, the monomer compound and the crosslinking reagent are introduced to a plasma deposition chamber in the liquid phase and the volumetric ratio of the crosslinking reagent to the monomer compound is from 1:99 to 90:10, or from 1:99 to 50:50, or from 1:99 to 30:70.

In an embodiment, the volumetric ratio of the crosslinking reagent to the monomer compound in step (ii) is from 1:99 to 25:75, from 1:99 to 20:80, from 5:95 to 20:80, or from 5:95 to 15:85. In an embodiment, the volumetric ratio of the crosslinking reagent to the monomer compound is about 10:90.

In an embodiment, the volumetric ratio of the crosslinking reagent to the monomer compound in step (ii) is from 1:99, 2:98, 3:97, 4:96, 5:95, 6:96, 7:93, 8:92, 9:91 or 10:90, and/or the volumetric ratio of the crosslinking reagent to the monomer compound is up to 90:10, 80:20, 70:30, 60:40, 50:50, 40:60, 30:70, 29:71, 28:72, 27:73, 26:74, 25:75, 24:76, 23:77, 22:78, 21:79, 20:80, 19:81, 18:82, 17:83, 16:84, 15:85, 14:86, 13:87, 12:88, 11:89 or 10:90.

As would be known to a skilled person, it is common in the art of plasma deposition to use the measurement of volumetric ratio when introducing reagents into a plasma deposition chamber. Alternatively, the ratio between reagents such as monomer compounds and crosslinking reagents can be expressed as the molar ratio at which reagents are introduced into the chamber. This is known as the molar input flow ratio.

In an embodiment, in step (ii) of the method according to the first aspect of the invention, the monomer compound and the crosslinking reagent are introduced to a plasma deposition chamber, optionally in the liquid phase, and the molar input flow ratio of the crosslinking reagent to the monomer compound is from 1:20 to 10:1, or from 1:20 to 1:1.

In an embodiment, the molar input flow ratio of the crosslinking reagent to the monomer compound is from 1:20 to 1:2, from 1:15 to 1:5, or from 1:14 to 1:6.

In an embodiment, the molar input flow ratio of the crosslinking reagent to the monomer compound in step (ii) is from 1:20, 1:19, 1:18, 1:17, 1:16, 1:15, 1:14, 1:13, 1:12, 1:11, 1:10, 1:9, 1:8, 1:7, 1:6, 1:5, 1:4, 1:3 or 1:2, and/or the molar input flow ratio of the possible range for the crosslinking reagent to the monomer compound is up to 10:1, 9:1, 8:1, 7:1, 6:1, 5:1, 4:1, 3:1, 2:1, 1:1, 1:2, 1:3, 1:4, 1:5, 1:6, 1:7, 1:8, 1:9, 1:10, 1:11, 1:12, 1:13, 1:14, 1:15, 1:16, 1:17, 1:18 or 1:19.

The volumetric ratio of the crosslinking reagent to the monomer compound can easily be converted to the molar ratio of the crosslinking reagent to the monomer compound and vice versa for particular monomer compounds and crosslinking reagents.

For example, when the crosslinking reagent and the monomer compound are introduced to a plasma deposition chamber in the liquid phase and the volumetric ratio of the crosslinking reagent to the monomer compound is 10:90, if the crosslinking reagent is DVA and the monomer compound is 1H,1H,2H,2H-perfluorooctyl acrylate (PFAC6), the molar input flow ratio of DVA to PFAC6 is about 1:6.

Similarly, when the crosslinking reagent and the monomer compound are introduced to a plasma deposition chamber in the liquid phase and the volumetric ratio of the crosslinking reagent to the monomer compound is 5:95, if the crosslinking reagent is DVA and the monomer compound is PFAC6, the molar input flow ratio of DVA to PFAC6 is about 1:13.

In general, in a plasma deposition process an item to be treated is placed in a plasma deposition chamber, a glow discharge is ignited within said chamber, and a suitable voltage is applied, which may be either continuous wave or pulsed. The glow discharge is suitably ignited by applying a high frequency voltage, for example at 13.56 MHz.

Before the monomer compound and/or the crosslinking agent enter the deposition chamber each may be in the form of a gas, liquid or a solid (for example a powder) at room temperature. However, it is the preferred that the monomer compound and/or the crosslinking reagent are both liquid at room temperature, and most preferably that the monomer and crosslinking agent liquids are miscible.

The crosslinking agent may be miscible with the monomer and so introduced together or separately into the plasma chamber. Or the crosslinking agent may be immiscible with the monomer and introduced separately into the plasma chamber. In this context, the term “miscible” means that the crosslinking agent is soluble in the monomer, and when mixed they form a solution of uniform composition. The term “immiscible” is used to mean that the crosslinking agent is only partly soluble or insoluble in the monomer, and so either forms an emulsion or separates out into two layers.

The monomer compound and/or the crosslinking agent will suitably be in a gaseous state in the plasma. The plasma may simply comprise a vapour of the monomer compound and/or the crosslinking agent. Such a vapour may be formed in-situ, with the compounds being introduced into the chamber in liquid form. The monomer may also be combined with a carrier gas, in particular, an inert gas such as helium or argon.

In preferred embodiments, the monomer and/or the crosslinking agent may be delivered into the chamber by way of an aerosol device such as a nebuliser or the like, as described for example in WO 2003/097245 and WO 2003/101621. In such an arrangement a carrier gas may not be required, which advantageously assists in achieving high flow rates.

The exact flow rate of the monomer compound and/or the crosslinking reagent into the chamber may depend to some extent on the nature of the particular monomer compound and/or the crosslinking reagent being used, the nature of the substrate, the desired coating properties, and the plasma chamber volume. In some embodiments of the invention, the monomer compound and/or the crosslinking reagent is introduced into the chamber at a gas flow rate in the range of at least 1 sccm (standard cubic centimetre per minute) and preferably in the range of from 1 to 2500 sccm, from 1 to 2000 sccm, from 1 to 1500 sccm, from 1 to 1000 sccm, from 1 to 750 sccm, from 1 to 500 sccm, from 1 to 250 sccm, from 1 to 200 sccm, from 1 to 100 sccm or from 5 to 60 sccm.

The monomer compound and/or the crosslinking reagent gas flow can be calculated from the liquid monomer flow, for example by using the ideal gas law, i.e. assuming that the monomer in the chamber acts like an ideal gas where one mole of gas at 273 K and 1 atmospheric pressure (STP) occupies a volume of 22400 cm³.

The step of exposing a connecting element (with a protective material) to a plasma may comprise a pulsed (PW) deposition step. Alternatively, or in addition, the step of exposing the connecting element (with a protective material) to a plasma may comprise a continuous wave (CW) deposition step.

The term pulsed may mean that the plasma cycles between a state of no (or substantially no) plasma emission (off-state) and a state where a particular amount of plasma is emitted (on-state). Alternatively, pulsed may mean that there is continuous emission of plasma but that the amount of plasma cycles between an upper limit (on-state) and lower limit (off-state).

For pulsed plasmas, higher average powers can be achieved by using higher peak powers and varying the pulsing regime (i.e. on/off times).

Optionally the voltage is pulsed in a sequence in which the ratio of the time on/time off is in the range of from 0.001 to 1, optionally 0.002 to 0.5. For example, time on may be 10-500 μs, or 35-45 μs, or 30-40 μs, such as about 36 μs; and time off may be from 0.1 to 30 ms, or 0.1 to 20 ms, or 5 to 15 ms, for example 6 ms. Time on may be 35 μs, 40 μs, 45 μs. Time off may be 0.1, 1, 2, 3, 6, 8, 10, 15, 20, 25 or 30 ms.

Optionally the voltage is applied as a pulsed field for a period of from 30 seconds to 90 minutes. Optionally the voltage is applied as a pulsed field for from 5 to 60 minutes.

The RF power can be supplied from 1 to 2000 W, for example from 50 to 1000 W, from 100 to 500 W, from 125 to 250 W.

The peak power can be from 1 to 2000 W, for example from 50 to 1000 W, from 100 to 500 W, from 125 to 250 W, or about 160 W.

The peak power to monomer flow ratio for a continuous wave plasma or a pulsed plasma may be from 2 to 60 W/sccm, from 2 to 40 W/sccm, from 2 to 25 W/sccm, or from 5 to 20 W/sccm.

During exposure of a substrate to a continuous wave plasma or a pulsed plasma, the plasma can have a peak power density of from 0.001 to 40 W/litre, or at least 2 W/litre, or about 20 W/litre.

In an embodiment, the protective material has a thickness of from 0.1 mm to 5 mm, for example from 0.5 mm to 2 mm, or about 1 mm.

In an embodiment, the thickness of the protective material is from 0.1 mm, 0.2 mm, 0.3 mm, 0.4 mm, 0.5 mm, 0.6 mm, 0.7 mm, 0.8 mm or 0.9 mm, and/or the thickness of the protective material is up to 5 mm, 4 mm, 3 mm, 2.5 mm, 2 mm, 1.5 mm, 1.4 mm, 1.3 mm, 1.2 mm, 1.1 mm or 1 mm.

In an embodiment, the overlying coating layer has a thickness of from 250 to 10000 nm, from 500 to 8000 nm, from 1000 to 6000 nm, from 1500 to 5000 nm, or from 2000 to 4000 nm.

In an embodiment, the thickness of the overlying coating is from 250 nm, 500 nm, 750 nm, 1000 nm, 1100 nm, 1200 nm, 1300 nm, 1400 nm, 1500 nm, 1600 nm, 1700 nm, 1800 nm, 1900 nm, 2000 nm, 2100 nm, 2200 nm, 2300 nm, 2400 nm or 2500 nm, and/or the thickness of the overlying coating is up to 10000 nm, 9000 nm, 8000 nm, 7000 nm, 6000 nm, 5500 nm, 5000 nm, 4900 nm, 4800 nm, 4700 nm, 4600 nm, 4500 nm, 4400 nm, 4300 nm, 4200 nm, 4100 nm, 4000 nm, 3900 nm, 3800 nm, 3700 nm, 3600 nm, 3500 nm, 3400 nm, 3300 nm, 3200 nm, 3100 nm, 3000 nm, 2900 nm, 2800 nm, 2700 nm, 2600 nm, 2500 nm, 2400 nm, 2300 nm, 2200 nm, 2100 nm, 2000 nm or 1900 nm.

In an embodiment, the overlying coating may be conformal, which can mean that it takes the 3D shape of the protective material and covers substantially an entire surface of at least the protective material. This has the advantage of ensuring that the coating has sufficient thickness to give optimal functionality over an entire surface of the protective material.

In an embodiment of the method according to the first aspect of the invention, the method further comprises depositing one or more additional coating layers.

In an embodiment of the method according to the first aspect of the invention, the second connecting element is not coated with a protective material and/or an overlying coating. In an embodiment, the second connecting element is not coated.

In an alternative embodiment of the method according to the first aspect of the invention, the method comprises also depositing a protective material as described above, and optionally an overlying coating as described above, on the second connecting element, before making the connection in step (iii).

In an embodiment of the method according to the first aspect of the invention, making the connection between the first connecting element and the second connecting element in step (iii) involves punching the protective material, and optionally the overlying coating, prior to making the connection.

The second connecting element may be pushed into or through the protective material, and optionally through the overlying coating, without first punching the protective material and optionally the overlying coating. However, punching the protective material prior to making the electrical can make it easier to push the second connecting element into or through the protective material.

In an embodiment of the method according to the first aspect of the invention, the method further comprises cleaning, etching or activating the connecting element before depositing the protective material in step (i). This preliminary step can act as an activation step, preparing the connecting element prior to deposition of a coating. The purpose of the step can, for example, be to make the connecting element chemically receptive to the coating (e.g. oxidise metal) and/or physically roughened to allow the coating to ‘key-in’ to the substrate (e.g. enhance mechanical interlocking).

In an embodiment, in the preliminary step a continuous power plasma can be applied to the connecting element. The preliminary step may be conducted in the presence of an inert gas. In an embodiment, the preliminary step is conducted in the presence of helium and/or oxygen.

According to a second aspect of the invention, there is provided a protected connection obtainable by the method according to the first aspect of the invention.

According to a third aspect of the present invention there is provided a connector comprising a first connecting element and a second connecting element forming a connection, the connection being protected by a dot of protective material bearing an overlying coating, wherein a portion of the protective material is interposed between the connecting elements.

The first connecting element, the second connecting element, the connector, the connection, the protective material, and the overlying coating may be as described or defined in respect of the first aspect of the invention.

Throughout the description and claims of this specification, the words “comprise” and “contain” and variations of the words, for example “comprising” and “comprises”, mean “including but not limited to”, and do not exclude other components, integers or steps. Moreover the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Within the scope of this application it is expressly intended that the various aspects, embodiments, examples and alternatives set out in the preceding paragraphs, in the claims and/or in the following description and drawings, and in particular the individual features thereof, may be taken independently or in any combination. That is, all embodiments and/or features of any embodiment can be combined in any way and/or combination, unless such features are incompatible.

One or more embodiments of the invention will now be described, by way of example only, with reference to the accompanying drawings, in which:

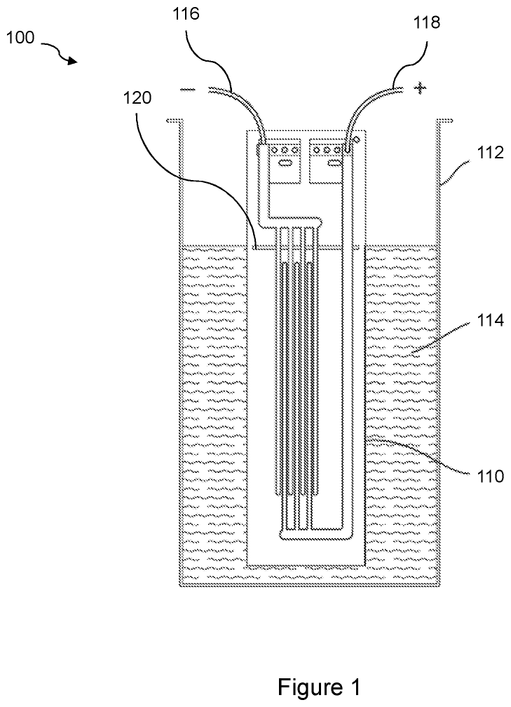

FIG. 1 shows electrical test apparatus for determining the resistance of a coating.

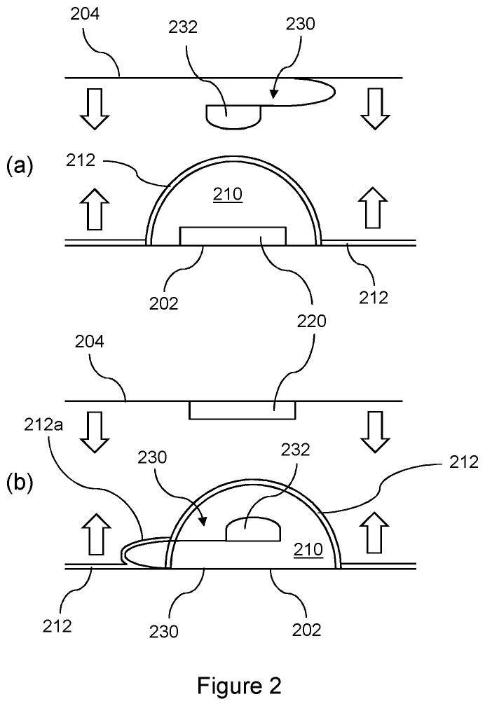

FIG. 2 shows schematic examples of a protective material (in the form of a gel blister) dispensed over (a) a contact pad and (b) a spring connector.

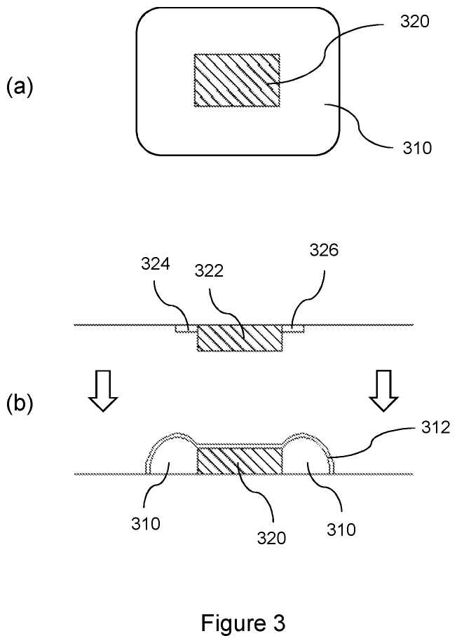

FIG. 3 shows schematic diagrams of (a) a plan view of a board-to-board socket (or header) surrounded by protective material and (b) a side view of a board-to-board socket (or header) surrounded by protective material, after plasma coating.

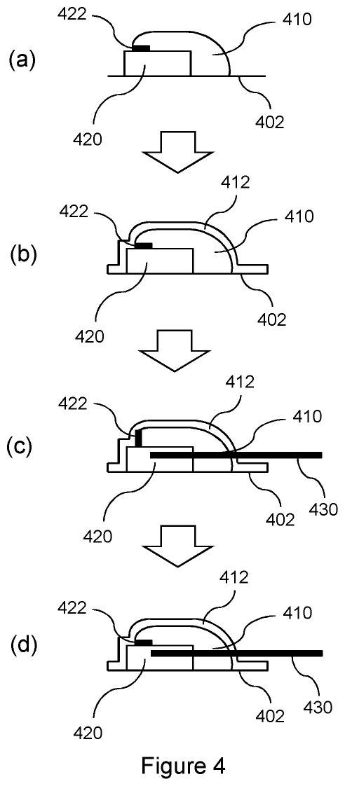

FIG. 4 shows a schematic diagram of the process of applying a protective material and a plasma coating to a ZIF connector, then inserting the cable through the protective material and plasma coating to make an electrical connection.

### EXAMPLES

Plasma Deposition Process

Plasma polymerization experiments were carried out in a metallic reaction chamber with a working volume of 22 litres. The chamber consisted of two parts, a shallow cuboid cavity with a single open face, oriented vertically, which was sealed to a solid metallic door via a Viton O ring on the outer edge. All surfaces were heated to 37° C. Inside the chamber was a single perforated metal electrode, area per the open face of the cavity, also oriented vertically and attached via connections at the corners to the door, fed by an RF power unit via a connection through the centre of the metallic door. For pulsed plasma deposition the RF power unit was controlled by a pulse generator.

The rear of the chamber was connected via a larger cavity, achieving a total volume of 125 L, to a metal pump line, pressure controlling valve, a compressed dry air supply and a vacuum pump. The door of the chamber comprised several cylindrical ports for connection to pressure gauges, monomer delivery valves (inner surfaces of which were heated to 70° C.), temperature controls and gas feed lines which were in turn connected to mass flow controllers.

In each experiment a sample was positioned vertically on nylon pegs attached to the perforated electrode, facing the door.

The reactor was evacuated down to base pressure (typically <10 mTorr). Process gas was delivered into the chamber using the mass flow controllers, with typical gas flow values being between 2-25 sccm. The monomer was delivered into the chamber, with typical monomer gas flow values being between 5-60 sccm. The chamber was heated to 37° C. The pressure inside the reactor was maintained at between 20-30 mTorr. The plasma was produced using RF at 13.56 MHz. The process usually contains at least the steps of a continuous wave (CW) plasma and a pulsed wave (PW) plasma. Optionally, these steps can be proceeded by an initial activation step using a continuous wave (CW) plasma. The activation CW plasma, if used, was for 1 minute, the CW plasma was for 1 or 4 minutes and the duration of the PW plasma varied in different experiments. The peak power setting was 160 W in each case, and the pulse conditions were time on (tₒₙ)=37 μs and time off (t_{off})=10 ms. At the end of the deposition the RF power was switched off, the monomer delivery valves stopped and the chamber pumped down to base pressure. The chamber was the vented to atmospheric pressure and the coated samples removed.

For each experiment, 4-6 test printed circuit boards (PCBs) and accompanying Si wafers were used. The Si wafers allow physical properties of the formed coating to be measured, for example AFM for surface morphology and XRR for coating density. The metal tracks of the test PCBs were gold coated copper. The Si wafers were placed on the top front side of the PCBs.

Analytical Methods

A number of properties of exemplary coated surfaces formed according to the invention were investigated, using the following methods.

Resistance in Tap Water

This test method has been devised to evaluate the ability of different coatings to provide an electrical barrier on printed circuit boards and predict the ability of a smart phone to pass the IEC 60529 14.2.7 (IPX7) test. The method is designed to be used with tap water. This test involves measuring the current voltage (IV) characteristics of a standardised printed circuit board (PCB) in water. The PCB has been designed with spacing of 0.5 mm between electrodes to allow assessment of when electrochemical migration occurs across the tracks in water. The degree of electrochemical activity is quantified by measuring current flow; low current flow is indicative of a good quality coating. The method has proved to be extremely effective at discriminating between different coatings. The performance of the coatings can be quantified, e.g. as a resistance at 4 and 8V and 21 V. The measured resistance on the untreated test device is about 100 ohms when 16V/mm are applied.

FIG. 1 shows an electrical test apparatus 100. The coated PCB 110 to be tested is placed into a beaker 112 of water 114 and connected to a power source (not shown) via connections 116,118. The coated PCB 110 is centred horizontally and vertically in the beaker 112 to minimise effects of local ion concentration (vertical location of the coated PCB 110 is very important; water 114 level should be to the blue indicator line 120). When the coated PCB 110 is connected, the power source is set to the desired voltage and the current is immediately monitored. The voltage applied is for example 8V and the coated PCB 110 is held at the set voltage for 13 minutes, with the current being monitored continuously during this period.

The coatings formed by the different process parameters are tested. It has been found that when coatings have resistance values higher than 10 MOhms, the coated device will successfully pass an IPX7 test. The nature of the device being coated (for example the type of smart phone) will influence the test, for example due to the variations in materials, ingress points, power consumption etc).

Resistance in Salt Water

This test method is identical to the method described above for “Resistance in tap water”, except that salt water is used instead of tap water. The composition of the salt water is 5% w/v NaCl, i.e. 5 g NaCl per 100 ml water.

Coating Thickness

The thickness of the coatings formed was measured using spectroscopic reflectometry apparatus (Filmetrics F20-UV) using optical constants verified by spectroscopic elipsometry.

Spectroscopic Ellipsometry

Spectroscopic ellipsometry is a technique for measuring the change in polarization between incident polarized light and the light after interaction with a sample (i.e. reflected, transmitted light etc). The change in polarization is quantified by the amplitude ratio ψ and phase difference Δ. A broad band light source is used to measure this variation over a range of wavelengths and the standard values of ψ and Δ are measured as a function of wavelength. The ITAC MNT Ellipsometer is an AutoSE from Horiba Yvon which has a wavelength range of 450 to 850 nm. Many optical constants can be derived from the ψ and Δ values, such as film thickness and refractive index.

Data collected from the sample measurements includes the intensities of the harmonics of the reflected or transmitted signal in the predefined spectral range. These are mathematically treated to extract intensity values called Is and Ic as f(I). Starting from Ic and Is the software calculates ψ and Δ. To extract parameters of interest, such as thickness or optical constants, a model has to be set up to allow theoretical calculation of ψ and Δ. The parameters of interest are determined by comparison of the theoretical and experimental data files to obtain the best fit (MSE or X²). The best fit for a thin layer should give an X²<3, for thicker coatings this value can be as large as 15. The model used is a three layer Laurentz model including PTFE on Si substrate finishing with a mixed layer (PTFE+voids) to account for surface roughness.

Spectroscopy Reflectrometry

Thickness of the coating is measured using a Filmetrics F20-UV spectroscopy reflectrometry apparatus. This instrument (F20-UV) measures the coating's characteristics by reflecting light off the coating and analyzing the resulting reflectance spectrum over a range of wavelengths. Light reflected from different interfaces of the coating can be in- or out-of-phase so these reflections add or subtract, depending upon the wavelength of the incident light and the coating's thickness and index. The result is intensity oscillations in the reflectance spectrum that are characteristic of the coating.

To determine the coating's thickness, the Filmetrics software calculates a theoretical reflectance spectrum which matches as closely as possible to the measured spectrum. It begins with an initial guess for what the reflectance spectrum should look like, based on the nominal coating stack (layered structure). This includes information on the thickness (precision 0.2 nm) and the refractive index of the different layers and the substrate that make up the sample (refractive index values can be derived from spectroscopic ellipsometry). The theoretical reflectance spectrum is then adjusted by adjusting the coating's properties until a best fit to the measured spectrum is found.

Alternative techniques for measuring thickness are stylus profilometry and coating cross sections measured by SEM.

Monomer Compound

The monomer compound used in these examples was PFAC6, i.e. 1H,1H,2H,2H-perfluorooctylacrylate (CAS #17527-29-6) of formula:

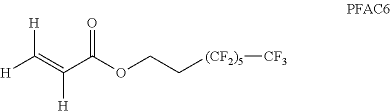

Crosslinking Agent

The crosslinking agent used in these examples was divinyl adipate (DVA) (CAS #4074-90-2) of formula:

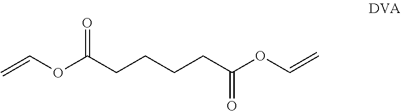

### Example A—Formation of Plasma Coating

A 2500 nm thick coating is deposited onto printed circuit boards (PCBs) and accompanying Si wafers in a gas phase plasma deposition process as described above, using a perfluorinated acrylate monomer, PFAC6, and a cross-linker, DVA, which were introduced to the plasma deposition chamber in the liquid phase, pre-mixed at the volumetric ratio 9:1.

The barrier performance of the coating on the PCBs is tested via the tests described above and the results are shown in Table 2.

TABLE 2
Performance of the plasma deposited coating

| | |
|---|---|
| Resistance in tap water | >10 MOhms |
| (8 V, Ω) | |
| Average from all samples | |
| Resistance in 5% salt water | >10 MOhms |
| (8 V, Ω) | |
| Only one sample | |

### Example 1—Using a Self-Healing Gel to Protect a Spring Connector

A self-healing gel is dispensed on an area of a printed circuit board (PCB) where an electrical connection needs to be made, for example a spring connector or a contact pad. Dispense of the gel can be manual or automated. The gel can be dispensed as one or more discrete units. The dimensions of a unit once dispensed can be around 2.5 mm in width and 1 mm in height.

The self-healing gel is a silicone rubber. The base material (before curing) is a silicone rubber blend. The catalyst contains a platinum additive.

The self-healing gel has the following properties:
Base material viscosity before cure: 55,000 cPs at 25° C.
Catalyst viscosity before cure: 1,000 cPs at 20° C.
Mixed viscosity before cure: 42,000 cPs at 23° C.
Mix ratio: 10:1 base material: catalyst by volume
Curing mechanism: UV curable with broadband UV source
Penetration hardness after cure (ISO 2137, 9.38 g hollow cone): 70 mm/10
Dielectric strength: >23 kV

The gel is cured under a 365 nm UV LED (cure time 19 s, distance 10 mm) and then treated with a fluoropolymer plasma deposited coating as described in Example A.

After the fluoropolymer treatment, the gel can be punched prior to reassembly using a spring-loaded punch at defined speed and diameter to ensure that the contact can push through the gel.

FIG. 2 (a) shows a schematic example of a PCB 202 having a contact pad 220 for connection with a component 204 having a spring connector 230. In this example, gel 210 is dispensed over the contact pad 220 such that the contact pad 220 is completely encased within the gel 210. A fluoropolymer coating 212 is subsequently deposited over the PCB 202 and the gel 210. As the component 204 is brought towards the PCB 202 to make a connection, a contact portion 232 of the spring connector 230 comes into contact with the fluoropolymer coating 212. The gel 210 under the fluoropolymer coating 212 acts as a cushion, thereby making the fluoropolymer layer 212 brittle. The contact portion 232 of spring connector 230 is therefore able to break through the brittle fluoropolymer layer 212 and engage with the contact pad 210 within the gel 210.

FIG. 2(b) shows a schematic diagram of a PCB having a spring connector 230 for connection with a component 204 having a contact pad 220. In this example, gel 210 is dispensed over the spring connector 230, such that a contact portion 232 of the spring connector 230 is completely encased within the gel 210. A fluoropolymer coating 212 is subsequently deposited over the PCB 202, part of the spring connector 230, and the gel 210. The gel 210 acts as a mask, thereby preventing coating of the contact portion 232 of the spring connector 230 by the fluoropolymer.

As the component 204 is brought towards the PCB 202 to make a connection, the gel 210 under the fluoropolymer coating 212 acts as a cushion and allows the contact pad 220 to push through the brittle fluoropolymer layer 212. No demasking step is required and the contact pin 232 and pad 220 is protected from corrosion by the self-healing gel 210.

Alternatively, a separate tool may be used to break the a hole in the fluoropolymer layer 212 in a preliminary step prior to bringing the component 204 towards the PCB 202 to make a connection.

### Example 2—Using a Self-Healing Gel to Protect a Board-to-Board Connector

A self-healing gel is dispensed on an area of a printed circuit board (PCB) where an electrical connection needs to be made, for example around the perimeter of either the socket or header of a board-to-board connector pair. Dispense of the gel can be manual or automated and the thickness of the gel should be greater than the height of the component. The exact quantity of gel depends on the dimensions and layout of the board to board connector but there must be enough gel to cover and protect the outside terminals on the untreated connector, when the connectors are paired. The gel may be applied such that there is a gap between the board to board connector and gel. The gel may be applied only to those sides of the board to board connector that have exposed terminals.

The self-healing gel is a silicone rubber. The base material (before curing) is a silicone rubber blend. The catalyst contains a platinum additive.

The self-healing gel has the following properties:
Base material viscosity before cure: 55,000 cPs at 25° C.
Catalyst viscosity before cure: 1,000 cPs at 20° C.
Mixed viscosity before cure: 42,000 cPs at 23° C.
Mix ratio: 10:1 base material: catalyst by volume
Curing mechanism: UV curable with broadband UV source
Penetration hardness after cure (ISO 2137, 9.38 g hollow cone): 70 mm/10
Dielectric strength: >23 kV

Following dispense, the gel is cured under a 365 nm UV LED (cure time 19 s, distance 10 mm) then treated with a fluoropolymer plasma deposited coating as described in Example A.

The other connector does not need to be separately processed so the connecting pair can then be mated.

FIG. 3 shows schematic diagrams of (a) a plan view of a board-to-board socket 320 surrounded by gel 310 and (b) a side view of a board-to-board socket 320 surrounded by gel 310, after plasma coating to form a fluoropolymer plasma deposited coating 312. An (untreated) board-to-board header 322 is brought into contact with the board-to-board socket 320 and pushes through the fluoropolymer plasma deposited coating 312 to form a connection. Terminals 324, 326 on either side of the (untreated) board-to-board header 322 are protected by the gel 310 when the socket 320 and header 322 are paired. Alternatively, socket 320 may be a header and (untreated) header 322 may be a socket.

### Example 3—Using a Self-Healing Gel to Protect a ZIF Connector

A self-healing gel is dispensed on an area of a printed circuit board (PCB) where an electrical connection needs to be made, for example over a ZIF connector. Dispense of the gel can be manual or automated and the quantity of gel depends on the dimensions and layout of the ZIF connector. There must be enough gel to ensure the terminals on the inserted ZIF jumper cable are fully submerged and protected.

The self-healing gel is a silicone rubber. The base material (before curing) is a silicone rubber blend. The catalyst contains a platinum additive.

The self-healing gel has the following properties:
Base material viscosity before cure: 55,000 cPs at 25° C.
Catalyst viscosity before cure: 1,000 cPs at 20° C.
Mixed viscosity before cure: 42,000 cPs at 23° C.
Mix ratio: 10:1 base material: catalyst by volume
Curing mechanism: UV curable with broadband UV source
Penetration hardness after cure (ISO 2137, 9.38 g hollow cone): 70 mm/10
Dielectric strength: >23 kV

Following dispense, the gel is cured under a 365 nm UV LED (cure time 19 s, distance 10 mm) then treated with a fluoropolymer plasma deposited coating as described in Example A.

The ZIF cable does not need to be separately processed and can be inserted, through the gel, into the ZIF connector and the lever closed.

FIG. 4 shows a schematic diagram of the process of applying a gel and a plasma coating to a ZIF connector, then inserting the cable through the gel and plasma coating to make an electrical connection. In more detail, referring to FIG. 4(a), gel 410 is dispensed over a portion of a ZIF connector 420 on a PCB 402, the ZIF connector 420 having its lever 422 in the down (closed) position. A fluoropolymer coating 412 is subsequently deposited over the PCB 402, gel 410 and portion of the ZIF connector 420 not having gel 410 dispensed thereon, as shown in FIG. 4(b). The lever 422 is then moved into the up (open) position and a ZIF cable 430 inserted through the brittle fluoropolymer coating 412, and through the gel 410 into the ZIF connector 420, as shown in FIG. 4(c). Referring to FIG. 4(d), the lever 422 is returned to the down (closed) position to lock the ZIF cable 430 in the ZIF connector 420.

Gel 410 may be dispensed over a portion of a ZIF connector 420 when its lever 422 is in the up (open) position.

1. A method of forming a protected connection between a first connecting element, optionally mounted on a support, and a second connecting element, the method comprising:
(i) depositing a protective material on the first connecting element and/or on the support;
(ii) optionally depositing an overlying coating on the protective material; and
(iii) pushing the second connecting element and establishing a connection between the first connecting element and the second connecting element, the connection being protected by the protective material.

2. The method of claim 1, wherein step (iii) additionally comprises pushing the second connecting element into the protective material.

3. The method of claim 1 or 2, wherein step (iii) additionally comprises pushing the second connecting element through the overlying coating.

4. The method of any one of the preceding claims, wherein in step (i) the protective material is deposited on the first connecting element.

5. The method of any one of the preceding claims, wherein in step (iii) the second connecting element is pushed into the protective material, and optionally through the overlying coating, to establish a connection between the first connecting element and the second connecting element.

6. The method of any one of the preceding claims, wherein the support is a printed circuit board.

7. The method of any one of the preceding claims, the method comprising:
(i) depositing a protective material on the first connecting element;
(ii) optionally depositing an overlying coating on the protective material; and
(iii) pushing the second connecting element into the protective material, and optionally through the overlying coating, to establish a connection between the first connecting element and the second connecting element, the connection being protected by the protective material.

8. The method of any one of the preceding claims, wherein the protective material is a self-healing material.

9. The method of any one of the preceding claims, wherein the protective material is a gel.

10. The method of any one of the preceding claims, wherein the protective material has a hardness value of less than 100 according to Shore OO hardness, as determined by ASTM D2240.

11. The method of any one of the preceding claims, wherein the protective material has a hardness value of 1 mm/10 or more according to the penetration hardness scale as determined by ISO 2137, 9.38 g hollow cone.

12. The method of any one of the preceding claims, wherein depositing the protective material comprises use of a base material, which optionally comprises silicone rubber, and a catalyst, which optionally comprises platinum.

13. The method of any one of the preceding claims, wherein depositing the protective material comprises curing, optionally UV curing and/or thermal curing.

14. The method of claim 12 or 13, wherein the viscosity of a mixture of the base material and the catalyst is from 100 cPs to 400,000 cPs.

15. The method of any one of the preceding claims, wherein the connection is an electrical connection.

16. The method of claim 15, wherein the first connecting element and the second connecting element constitute an electrical connector, and the electrical connector is selected from electrical connectors that include spring-type contacts, electrical connectors with contacts that comprise spring-loaded pins, plug-in type electrical connectors, contact pads, board-to-board (B2B) connectors, and zero insertion force (ZIF) connectors.

17. The method of any one of the preceding claims, wherein the method comprises step (ii) of depositing an overlying coating on the protective material.

18. The method of any one of the preceding claims, wherein depositing the overlying coating in step (ii) comprises forming a plasma deposited layer.

19. The method of claim 18, wherein depositing the overlying coating in step (ii) comprises exposing the protective material to a plasma comprising a monomer compound for a period of time sufficient to allow the overlying coating to form.

20. The method of claim 19, wherein the monomer compound is a compound of formula (I): 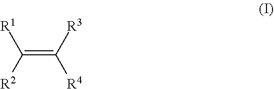
wherein
each of R¹, R² and R⁴ is independently selected from hydrogen, halogen, optionally substituted branched or straight chain C₁-C₆ alkyl, optionally substituted C₃-C₈ cycloalkyl, optionally substituted C₃-C₁₂ aryl, and
R³ is selected from: 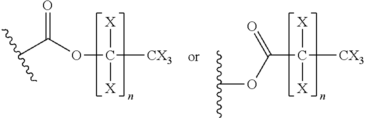
wherein each X is independently selected from hydrogen, halogen, optionally substituted branched or straight chain C₁-C₆ alkyl, optionally substituted C₃-C₈ cycloalkyl, and optionally substituted C₃-C₁₂ aryl, and
n is an integer from 1 to 27.

21. The method of claim 19 or 20, wherein the monomer compound is a compound of formula (Ia): 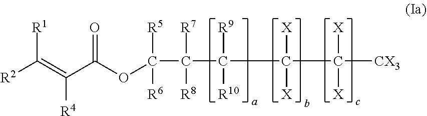
wherein
each of R¹, R², R⁴, and R⁵ to R¹⁰ is independently selected from hydrogen and optionally substituted C₁-C₆ branched or straight chain alkyl;
each X is independently selected from hydrogen and halogen;
a is from 0 to 10; b is from 2 to 14; and c is 0 or 1;
or
wherein the monomer compound is a compound of formula (Ib): 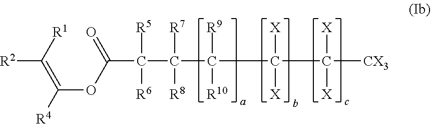
wherein
each of R¹, R², R⁴, and R⁵ to R¹⁰ is independently selected from hydrogen and optionally substituted C₁-C₆ branched or straight chain alkyl;
each X is independently selected from hydrogen and halogen;
a is from 0 to 10; b is from 2 to 14; and c is 0 or 1.

22. The method of claim 21, wherein a and c are each independently 0 or 1; and b is from 3 to 7.

23. The method of any one of claims 20 to 22, wherein each X is F.

24. The method of any one of claims 20 to 23, wherein each of R¹, R² and R⁴ is independently selected from hydrogen and methyl.

25. The method of claim 24, wherein each of R¹, R² and R⁴ is hydrogen.

26. The method of any one of claims 21 to 25, wherein each of R⁵ to R¹⁰ is independently selected from hydrogen and methyl.

27. The method of claim 26, wherein each of R⁵ to R¹⁰ is hydrogen.

28. The method of any one of claims 20 to 27, wherein the monomer compound is a compound of formula (Ic): 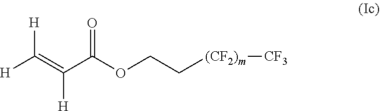
wherein m is from 1 to 10.

29. The method of claim 28, wherein the compound of formula (Ic) is selected from 1H,1H,2H,2H-perfluorohexyl acrylate (PFAC4), 1H,1H,2H,2H-perfluorooctyl acrylate (PFAC6), 1H,1H,2H,2H-perfluorodecyl acrylate (PFAC8) and 1H,1H,2H,2H-perfluorododecyl acrylate (PFAC10).

30. The method of any one of claims 20 to 27, wherein the monomer compound is a compound of formula (Id): 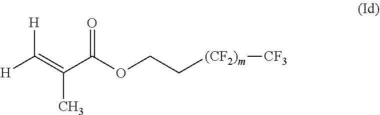
wherein m is from 1 to 10.

31. The method of claim 30, wherein the compound of formula (Id) is selected from 1H,1H,2H,2H-perfluorohexyl methacrylate (PFMAC4), 1H,1H,2H,2H-perfluorooctyl methacrylate (PFMAC6) and 1H,1H,2H,2H-perfluorodecyl methacrylate (PFMAC8).

32. The method of any one of claims 19 to 31, wherein in step (ii), the protective material is exposed to a plasma comprising the monomer compound and a crosslinking reagent.

33. The method of claim 32, wherein the crosslinking reagent comprises two or more unsaturated bonds attached by means of one or more linker moieties.

34. The method of claim 32 or 33, wherein the crosslinking reagent has a boiling point of less than 500° C. at standard pressure.

35. The method of any one of claims 32 to 34, wherein the crosslinking reagent is independently selected from a compound of formula (II) or (III): 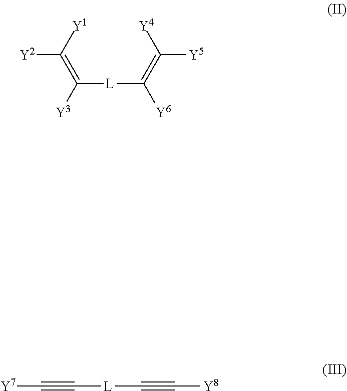
wherein
Y¹, Y², Y³, Y⁴, Y⁵, Y⁶, Y⁷ and Y⁸ are each independently selected from hydrogen, optionally substituted branched or straight chain C₁-C₆ alkyl, optionally substituted C₁-C₆ cycloalkyl, and optionally substituted C₁-C₆ aryl; and
L is a linker moiety.

36. The method of claim 35, wherein for the compound of formula (II), group L has the formula: 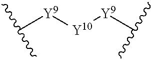
wherein
each Y⁹ is independently selected from a bond, —O—, —O—C(O)—, —C(O)—O—, —Y¹¹—O—C(O)—, —C(O)—O—Y¹¹—, —OY¹¹—, and —Y¹¹O—, wherein Y¹¹ is an optionally substituted branched, straight chain or cyclic C₁-C₈ alkylene; and
Y¹⁰ is selected from an optionally substituted branched, straight chain or cyclic C₁-C₈ alkylene and a siloxane group.

37. The method of any one of claims 32 to 36, wherein the crosslinking reagent is independently selected from divinyl adipate (DVA), 1,4-butanediol divinyl ether (BDVE), 1,4-cyclohexanedimethanol divinyl ether (CDDE), 1,7-octadiene (17OD), 1,2,4-trivinylcyclohexane (TVCH), 1,3-divinyltetramethyldisiloxane (DVTMDS), diallyl 1,4-cyclohexanedicarboxylate (DCHD), 1,6-divinylperfluorohexane (DVPFH), 1H,1H,6H,6H-perfluorohexanediol diacrylate (PFHDA) and glyoxal bis(diallyl acetal) (GBDA).

38. The method of claim 37, wherein the crosslinking reagent is divinyl adipate (DVA).

39. The method of any one of claims 35 to 38, wherein for the compound of formula (III), group L is selected from a branched or straight chain C₁-C₈ alkylene or an ether group.

40. The method of any one of claims 32 to 39, wherein in step (ii), the monomer compound and the crosslinking reagent are introduced to a plasma deposition chamber in the liquid phase and the volumetric ratio of the crosslinking reagent to the monomer compound is from 1:99 to 20:80.

41. The method of claim 40, wherein in step (ii) the volumetric ratio of the crosslinking reagent to the monomer compound is from 5:95 to 15:85.

42. The method of any one of claims 32 to 41, wherein in step (ii), the monomer compound and the crosslinking reagent are introduced to a plasma deposition chamber and the molar input flow ratio of the crosslinking reagent to the monomer compound is from 1:20 to 1:1.

43. The method of claim 42, wherein in step (ii) the molar input flow ratio of the crosslinking reagent to the monomer compound is from 1:14 to 1:6.

44. The method of any one of the preceding claims, wherein the protective material has a thickness of from 0.1 mm to 5 mm.

45. The method of any one of the preceding claims, wherein the overlying coating layer has a thickness of from 250 nm to 10000 nm.

46. The method of any one of the preceding claims, wherein the method further comprises depositing one or more additional coating layers.

47. The method of any one of the preceding claims, wherein the second connecting element is not coated.

48. The method of any one of claims 1 to 47, wherein the method further comprises depositing the protective material, and optionally the overlying coating, on the second connecting element before making the connection in step (iii).

49. The method of any one of the preceding claims, wherein making the connection between the first connecting element and the second connecting element in step (iii) involves punching the protective material, and optionally the overlying coating, prior to making the connection.

50. A protected connection obtainable by the method according to any one of claims 1 to 49.

51. A connector comprising a first connecting element and a second connecting element forming a connection, the connection being protected by a dot of protective material bearing an overlying coating, optionally wherein a portion of the protective material is interposed between the connecting elements.

52. The connector of claim 51, which is an electrical connector.

53. The connector of claim 52, wherein the connector is selected from the electrical connectors defined in claim 10.

54. The connector of any one of claims 51 to 53, wherein the protective material is as defined in any one of claim 8 to 11 or 44.

55. The connector of any one of claims 51 to 54, wherein the protective material is obtainable by deposition as defined in any one of claims 1 or 7 to 14.

56. The connector of any one of claims 51 to 55, wherein the overlying coating comprises a plasma deposited layer.

57. The connector of any one of claims 51 to 56, wherein the overlying coating is obtainable by deposition as defined in any one of claims 18 to 43.

58. The connector of any one of claims 51 to 57, wherein the overlying coating is as defined in claim 45.
